(19) United States
(12) Patent Application Publication
(10) Pub. No.: US 2025/0266262 A1
(43) Pub. Date: Aug. 21, 2025

(54) COMPONENT HAVING AT LEAST ONE FEATURE THAT HAS A VARYING CROSS-SECTIONAL SHAPE, SIZE, OR POSITION

(71) Applicant: Quantinuum LLC, Broomfield, CO (US)

(72) Inventors: Adam Jay OLLANIK, Boulder, CO (US); Rezlind BUSHATI, Rockville, MD (US); Susan Eileen SHORE, Golden Valley, MN (US); Matthew BLAIN, Broomfield, CO (US); Daniel Gerald OUELLETTE, Minneapolis, MN (US)

(21) Appl. No.: 19/011,350

(22) Filed: Jan. 6, 2025

Related U.S. Application Data
(60) Provisional application No. 63/554,624, filed on Feb. 16, 2024.

(51) Int. Cl. H01L 21/306; C23C 16/04; H01L 21/02; H01L 21/3065

(52) U.S. Cl. CPC H01L 21/30604; C23C 16/045; H01L 21/02164; H01L 21/3065

(57) ABSTRACT

In various aspects, a method of forming at least one feature on a substrate for a component of an electrical or optical device is provided. The method may include forming at least one cavity in a mold layer that is on the substrate. The mold layer may include a mold material. The method may include applying a feature material within each of the at least one cavity and on the substrate. The feature material may define the at least one feature.

### CROSS-REFERENCE TO RELATED APPLICATIONS

The present application is a nonprovisional application, which claims priority to and the benefit of U.S. Provisional Application No. 63/554,624, filed Feb. 16, 2024, the contents of which are incorporated by reference in its entirety.

### TECHNICAL FIELD

The present application relates generally to fabrication of components of an electrical and/or optical device that includes at least one feature formed on a substrate of the component. More specifically, the present application relates to forming each feature on the substrate such that each feature has a varying cross-sectional shape, a varying cross-sectional size, or a varying cross-sectional position.

### BACKGROUND

Components of electrical and/or optical devices often include features that are formed on a substrate, such as a semiconductor wafer. Conventional methods of forming these features may result in features that are uniform in out-of-plane dimensions, similar to an extrusion that only has a two-dimensional profile. Stated differently, conventional methods of forming features on a substrate may result in features that have a consistent cross-sectional shape, consistent cross-sectional size, and consistent cross-sectional position along a length of the conventional feature.

The inventors have identified numerous deficiencies and problems with the existing technologies in this field. Through applied effort, ingenuity, and innovation, many of these identified deficiencies and problems have been solved by developing solutions that are structured in accordance with the embodiments of the present disclosure, many examples of which are described in detail herein.

### BRIEF SUMMARY

In general, embodiments of the present disclosure provided herein include methods and apparatuses to provide for improved components for electrical and/or optical devices. The components may each include a substrate and at least one feature formed on the substrate. The embodiments of the present disclosure describe various methods to form features on the substrate such that each feature has a varying cross-sectional shape, a varying cross-sectional size, or a varying cross-sectional position.

In various aspects, a method of forming at least one feature on a substrate for a component of an electrical or optical device is provided. The method may include forming at least one cavity in a mold layer that is on the substrate. The mold layer may include a mold material. The method may include applying a feature material within each of the at least one cavity and on the substrate. The feature material may define the at least one feature.

In various examples, the method further includes removing the mold layer. The feature material that remains on the substrate after the mold layer is removed may define the at least one feature.

In various examples, the mold material of the mold layer includes silicon.

In various examples, applying the feature material within each of the at least one cavity includes using a conformal chemical vapor deposition process to apply the feature material.

In various examples, the feature material is a dielectric material.

In various examples, the feature material is a metallic material.

In various examples, forming the at least one cavity includes forming the at least one cavity completely through a mold thickness of the mold layer.

In various examples, the at least one feature has a height that is less than 5 microns.

In various examples, the at least one feature has a width that is less than 5 microns.

In various examples, forming the at least one cavity in the mold layer includes removing a portion of the mold material with a wet chemical etching process to form the at least one cavity.

In various examples, removing the portion of the mold material includes removing the portion of the mold material with potassium hydroxide (KOH).

In various examples, at least one cavity defines a frustrum shape.

In various examples, a void is formed within the feature material that defines the at least one feature.

In various examples, the void includes an ultra-high vacuum environment.

In various examples, the void includes a low-pressure environment.

In various examples, the at least one cavity defines an inverted frustrum shape.

In various examples, forming the at least one cavity in the mold layer includes removing a portion of the mold material with a dry etching process to form the at least one cavity.

In various examples, the dry etching process results in reduced etching as the portion of the mold material is removed, which results in a tapered shape.

In various examples, each of the at least one cavity defines a conical shape.

In various examples, the mold layer defines a mold thickness and the at least one cavity formed in the mold layer defines an opening that has a diameter. The mold thickness may be greater than the diameter of the opening.

In various examples, forming the at least one cavity in the mold layer includes removing a portion of the mold material with alternating steps of etching the mold material, and passivating the mold material.

In various examples, etching the mold material includes etching the mold material with sulfur hexafluoride (SF6) and passivating the mold material includes passivating the mold material with octafluorocyclobutane (C4F8).

In various examples, each cavity defines a scallop shape.

In various examples, inner walls of each cavity define a plurality of parabolic-shaped inner walls.

In various examples, a plurality of voids is formed within the feature material that is applied within the cavity.

In various examples, each void includes a low-pressure environment.

In various examples, each void includes an ultra-high vacuum environment.

In various examples, forming the at least one cavity in the mold layer includes removing a portion of the mold material with a reactive ion etching process to form the at least one cavity.

In various examples, the method includes positioning the substrate at an angle relative to a direction of travel of ions being used in the reactive ion etching process.

In various examples, the mold layer includes a plurality of layers. Aat least one layer may include the mold material and at least another layer may include a second mold material.

In various examples, the method includes applying a masking layer on at least a portion of at least one of the plurality of layers.

In various examples, the plurality of layers may include the second mold material, and wherein each layer that includes the second mold material is distinct from the other layers that comprise the second mold material.

In various examples, the at least one layer that includes the mold material has a different thickness than the at least one layer that includes the second mold material.

In various examples, at least one of the layers that includes the second mold material has a different thickness than another one of the layers that includes the second mold material.

In various examples, at least one of the layers that includes the second mold material has a same thickness than another one of the layers that comprise the second mold material.

In various examples, the layers that includes the second mold material and have the same thickness also have different volumes.

In various examples, at least one of the layers that includes the second mold material has a portion that is not vertically aligned with at least one other layer that includes the second mold material.

In various examples, the mold material is silicon and the second mold material is silicon oxide.

In various examples, the forming the at least one cavity in the mold layer includes using a single etch process that will etch the mold material differently than the second mold material.

In various examples, the forming the at least one cavity in the mold layer includes using a single etch process that results in a vertical etch component and an isotropic etch component of the mold material and the second mold material. The rate of the vertical etch component and/or the isotropic etch component may be higher for one of the mold material or the second mold material.

In various examples, the forming the at least one cavity in the mold layer includes using a single etch process that will etch the mold material vertically and the second mold material isotropically.

In various examples, the forming the at least one cavity in the mold layer includes etching the mold material and the second mold material vertically with a first etching process, and etching the second mold material with a second etching process that is chemically selective to etch the second mold material isotropically.

In various aspects, a method of forming at least one feature on a substrate is provided. The method may include bonding a self-assembled structure on the substrate, applying a feature material or a mold layer comprising a mold material on the substrate and around the self-assembled structure, and removing the self-assembled structure from the substrate and from the feature material or the mold layer.

In various examples, the method includes positioning a lattice tool on the substrate. The lattice tool may define a plurality of spaces. The method may include positioning a plurality of self-assembled structures within the lattice tool. Each self-assembled structure is positioned within a respective space of the plurality of spaces defined by the lattice tool. The method may include bonding each of the self-assembled structures on the substrate.

In various examples, the lattice tool is a hexagonal lattice tool.

In various examples, the self-assembled structure is a self-assembled nanosphere.

In various examples, the self-assembled structure is a self-assembled polystyrene nanosphere.

In various examples, the self-assembled structure is a silica (SiO2) nanosphere.

In various examples, the method further includes arranging a plurality of self-assembled structures on the substrate in a self-organized arrangement by suspending the plurality of self-assembled structures in a liquid suspension and allowing the liquid suspension to evaporate.

In various examples, the plurality of self-assembled structures are suspended in the liquid suspension on top of the substrate.

In various examples, the method includes applying the feature material on the substrate and around the self-assembled structure.

In various examples, the feature material is a dielectric material or a metallic material.

In various examples, the feature material is a reflective material having a reflectivity of at least 90%.

In various examples, the method includes applying a reflective coating on the feature material, the reflective coating having a reflectivity of at least 90%.

In various examples, the method includes applying the mold layer on the substrate and around the self-assembled structure.

In various examples, the method includes applying the feature material within a cavity that is formed in the mold layer. The cavity may be formed after the removing the self-assembled structure from the substrate and from the mold layer, and wherein the feature material defines the at least one feature.

In various examples, the applying the feature material within the cavity includes applying the feature material within the cavity with a conformal deposition process.

In various examples, the applying the feature material within the cavity includes enclosing the cavity to form a void within the feature material that defines the at least one feature.

In various examples, the void includes a low-pressure environment.

In various examples, the void includes an ultra-high vacuum environment.

In various examples, the at least one feature defines a hollow spherical shape.

In various examples, the method includes positioning or depositing a substance within the at least one feature.

In various examples, the substance is a medicinal substance.

In various examples, forming the at least one cavity in the mold layer that is on the substrate includes bonding a self-assembled structure on the substrate, and applying the mold layer on the substrate and around the self-assembled structure.

In various examples, the method includes removing the self-assembled structure from the substrate.

In various examples, the at least one feature formed on the substrate is for at least one of a component of an electrical or optical device or a nanoparticle.

In various aspects, a component for an electrical or optical device is provided. The component may include a substrate extending along a horizontal plane, and at least one feature on the substrate. The at least one feature may include a feature material, and the at least one feature may have a varying cross-sectional shape or position along at least two other horizontal planes.

In various examples, the feature material is a dielectric material.

In various examples, the feature material is a metallic material.

In various examples, the at least one feature has the varying cross-sectional shape along the at least two other horizontal planes.

In various examples, each feature has a first portion that has a first horizontal thickness and a second portion that has second horizontal thickness, and wherein a percent difference between the first horizontal thickness and the second horizontal thickness is at least five percent.

In various examples, the at least one feature has a pyramidal shape.

In various examples, the at least one feature has an inverted pyramidal shape.

In various examples, the at least one feature defines a void that is positioned within the at least one feature.

In various examples, the void includes a low-pressure environment.

In various examples, the void includes an ultra-high vacuum environment.

In various examples, the at least one feature has a tapered shape.

In various examples, the at least one feature has an inverted conical shape.

In various examples, the at least one feature has a scallop shape.

In various examples, an outer surface of the at least one feature defines a plurality of parabolic-shaped outer surfaces.

In various examples, the at least one feature includes a plurality of voids that are formed within the feature material of the at least one feature.

In various examples, each void includes a low-pressure environment.

In various examples, each void includes an ultra-high vacuum environment.

In various examples, the at least one feature has a varying cross-sectional position along the at least two other horizontal planes.

In various examples, the at least one feature has a consistent cross-sectional shape along the at least two other horizontal planes.

In various examples, the at least one feature extends at an angle relative to the horizontal plane. The angle may be at least 5 degrees and up to 85 degrees.

In various examples, each feature has a first portion that has a first horizontal thickness, a second portion that has a second horizontal thickness, and a third portion that has a third horizontal thickness, a first percent difference between the first horizontal thickness and the second horizontal thickness is at least five percent, and a second percent difference between the first horizontal thickness and the third horizontal thickness is less than five percent.

In various examples, a first feature of the at least one feature has a different shape than a second feature of the at least one feature.

In various examples, each of the first feature and the second feature comprise at least one protrusion, and wherein the second feature includes more protrusions than the first feature.

In various examples, the at least one feature has a three-dimensional lattice shape.

In various examples, the at least one feature has a portion that has concave shape.

In various examples, the feature material of the at least one feature is a reflective material having a reflectivity of at least 90%.

In various examples, the component includes a reflective coating positioned on the at least one feature. The reflective coating may have a reflectivity of at least 90%.

In various examples, the at least one feature has a plurality of portions that have a concave shape.

In various examples, the at least one feature has a spherical shape.

In various examples, the at least one feature defines a void that is positioned within the at least one feature.

In various examples, the void includes a low-pressure environment.

In various examples, the void includes an ultra-high vacuum environment.

In various examples, the at least one feature includes a substance encapsulated within the at least one feature.

In various examples, the at least one feature is a nanoparticle.

In various examples, the substance is a medicinal substance. The above summary is provided merely for purposes of summarizing some example embodiments to provide a basic understanding of some aspects of the present disclosure. Accordingly, it will be appreciated that the above-described embodiments are merely examples and should not be construed to narrow the scope or spirit of the present disclosure in any way. It will be appreciated that the scope of the present disclosure encompasses many potential embodiments in addition to those here summarized, some of which will be further described below. Other features, aspects, and advantages of the subject matter will become apparent from the description, the drawings, and the claims.

### BRIEF DESCRIPTION OF THE DRAWINGS

Having thus described certain example embodiments of the present disclosure in general terms above, non-limiting and non-exhaustive embodiments of the subject disclosure are described with reference to the following figures, which are not necessarily drawn to scale and wherein like reference numerals refer to like parts throughout the various views unless otherwise specified. The components illustrated in the figures may or may not be present in certain embodiments described herein. Some embodiments may include fewer (or more) components than those shown in the figures.

FIGS. 1A-1D provide cross-sectional, side views of at least a portion of a component during various manufacturing stages, in accordance with an example embodiment.

FIGS. 2A-2F provide cross-sectional, side views of at least a portion of a component 100 during various manufacturing stages are provided, in accordance with an example embodiment.

FIGS. 3A-3C provide cross-sectional, side views of at least a portion of a component during various manufacturing stages, in accordance with an example embodiment.

FIGS. 4A-4C provide cross-sectional, side views of at least a portion of a component during various manufacturing stages, in accordance with an example embodiment.

FIGS. 4D-4F provide cross-sectional, side views of at least a portion of a component during various manufacturing stages, in accordance with an example embodiment.

FIGS. 5A-5Dprovide cross-sectional, side views of at least a portion of a component during various manufacturing stages, in accordance with an example embodiment.

FIGS. 6A-6D provide cross-sectional, side views of at least a portion of a component during various manufacturing stages, in accordance with an example embodiment.

FIGS. 7A-7E provide cross-sectional, side views of at least a portion of a component during various manufacturing stages, in accordance with an example embodiment.

FIG. 8A provides a top view of at least a portion of a component during a manufacturing stage, in accordance with an example embodiment.

FIG. 8B provides a top view of at least a portion of a component during a manufacturing stage, in accordance with an example embodiment.

FIGS. 8C-8E provide cross-sectional, side views of at least a portion of the component of FIG. 8B during various manufacturing stages, in accordance with an example embodiment.

FIGS. 9A-9E provide cross-sectional, side views of at least a portion of a component during various manufacturing stages, in accordance with an example embodiment.

FIGS. 10A-10H provide cross-sectional, side views of at least a portion of a component during various manufacturing stages, in accordance with an example embodiment.

### DETAILED DESCRIPTION

One or more embodiments are now more fully described with reference to the accompanying drawings, wherein like reference numerals are used to refer to like elements throughout and in which some, but not all embodiments of the inventions are shown. In the following description, for purposes of explanation, numerous specific details are set forth in order to provide a thorough understanding of the various embodiments. It is evident, however, that the various embodiments can be practiced without these specific details. It should be understood that some, but not all embodiments are shown and described herein. Indeed, the embodiments may be embodied in many different forms, and accordingly this disclosure should not be construed as limited to the embodiments set forth herein. Rather, these embodiments are provided so that this disclosure will satisfy applicable legal requirements.

As used herein, the term “exemplary” means serving as an example, instance, or illustration. Any aspect or design described herein as “exemplary” is not necessarily to be construed as preferred or advantageous over other aspects or designs. Rather, use of the word exemplary is intended to present concepts in a concrete fashion. In addition, while a particular feature may be disclosed with respect to only one of several implementations, such feature may be combined with one or more other features of the other implementations as may be desired and advantageous for any given or particular application. Furthermore, to the extent that the terms “includes” and “including” and variants thereof are used in either the detailed description or the claims, these terms are intended to be inclusive in a manner similar to the term “comprising.”

As used herein, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

As used herein, the term “positioned on” refers to a first component being positioned on a second component such that they make contact.

As used herein, the term “cross-sectional position” refers to a position of a feature on an XY plane that extends horizontally (i.e., parallel to a horizontal plane defined by a surface of a substrate). The cross-sectional position may be defined by an X coordinate and a Y coordinate. The term “cross-sectional shape” refers to a shape of a feature along an intersection of an XY plane. The term “cross-sectional size” refers to a size of a feature (i.e., area and dimensions of the feature) along an intersection of an XY plane.

The term “varying cross-sectional position” refers to a feature that has different X coordinate and/or Y coordinate positions depending on the Z coordinate (i.e., a vertical location relative to the horizontal plane defined by the surface of the substrate). Stated differently, the feature may define a first XY coordinate at a first Z coordinate and a second XY coordinate at a second Z coordinate, the first XY coordinate being different than the second XY coordinate. The first XY coordinate may be located at or near a first end of the feature and the second XY coordinate may be located at or near a second end of the feature. In contrast, the term “consistent cross-sectional position” refers to a feature that has the same XY coordinates at all points along the Z direction for which the feature is located.

The term “varying cross-sectional shape” refers to a feature that has a first cross-sectional shape at a first Z coordinate that is different than at least a second cross-sectional shape at a second Z coordinate. In contrast, the term “consistent cross-sectional shape” refers to a feature that has the same cross-sectional shape at all points along the Z direction for which the feature is located.

The term “varying cross-sectional size” refers to a feature that has a first cross-sectional size at a first Z coordinate that is different than at least a second cross-sectional size at a second Z coordinate. In contrast, the term “consistent cross-sectional size” refers to a feature that has the same cross-sectional size at all points along the Z direction for which the feature is located.

As used herein, terms of approximation, such as “approximately,” “substantially,” or “about,” refer to being within manufacturing or engineering tolerances. For example, terms of approximation may refer to being within a five percent margin of error.

Various embodiments provide a component of an electrical or optical device having a varying cross-sectional shape or position and/or methods for fabricating such components. In various embodiments, the component is an integrated photonic and/or optical component that may be a passive or active component. Various embodiments, provide nanometer-scale structures, such as nanoparticles, and methods for fabricating such structures.

For example, in an example embodiment, a component for an electrical or optical device and/or a nanometer-scale structure is provided that includes a substrate extending along a horizontal plane; and at least one feature on the substrate. The at least one feature comprises a feature material and has a varying cross-sectional shape or position along at least two other horizontal planes. In an example embodiment, the nanometer-scale structure may be removed from the substrate for use. In an example embodiment, the component is fabricated or formed by forming at least one cavity in a mold layer that is on the substrate, wherein the mold layer comprises a mold material; applying a feature material within each of the at least one cavity and on the substrate; and removing the mold layer. The feature material that remains on the substrate after the mold layer is removed defines the at least one feature.

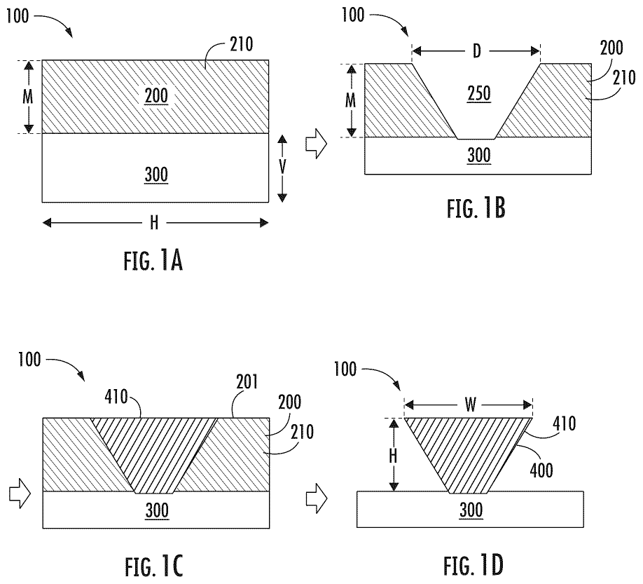

Referring now to FIGS. 1A-1D, cross-sectional, side views of at least a portion of a component 100 during various manufacturing or fabrication stages are provided, in accordance with an example embodiment. The component 100 can be a component 100 of an electrical and/or optical device (not depicted). In various examples, the electrical and/or optical device is a quantum information device, such as a quantum computer, an ion trap for a quantum computer, an atomic clock, or various other devices that are configured for sensing, such as photonic sensing, networking, cryptography, etc.

The component 100 may be a photonic component or an integrated optical component. For example, the component 100 can be a photonic coupling element, which may be a device that couples light from a guided mode to a free space propagating mode. The component 100 can be a metasurface of an optical device. For example, the component 100 can be a lens, a quarter or half waveplate metasurface, a spatial beam shaping metasurface, a beam directing metasurface, a lens for an image sensor, a laser beam splitter, or a color filter. In various examples, the component 100 can be a diffractive optic-phase-array or a hologram (e.g., lens hologram, graded arrays for beam direction, or spatial beam shaping holograms). In yet other examples, the component 100 can be a ring resonator, a power modulator, a waveguide, an input taper, a splitter (e.g., multi-mode interference (MMI), or y-branch), or a directional coupler. In yet other examples, the component 100 can be phonetic component 100, such as a metasurface for an antenna or a sound absorbing device.

The component 100 can include a substrate 300 that extends along a horizontal plane and at least one feature 400 that is positioned on the substrate 300. As will be discussed further, each feature 400 may have a varying cross-sectional shape or varying position along at least two other horizontal planes. The component 100 can include one feature 400 or a plurality of features 400, such as up to five-thousand features 400. Each feature 400 can be configured substantially similarly or at least some features 400 can be configured differently than other features 400 of the component 100. As will be appreciated in light of the present disclosure, different methodologies are provided that may be used to form various-shaped features 400. Each or some of these methodologies may be used to form features 400 that are different than other features 400.

With reference to FIG. 1A, the component 100 can be manufactured by applying (e.g., depositing) a mold layer 200 on a substrate 300. The substrate 300 can be a wafer that includes silicon (Si), such as silicon dioxide (SiO2) or silicon nitride (Si3N4), germanium (Ge), or a combination thereof. The substrate 300 can define a horizontal direction H and a vertical direction V that extends orthogonally to the horizontal direction H. For example, the vertical direction V extends out from the horizontal direction H. An upper surface of the substrate 300 can be substantially planar.

The mold layer 200 can include any mold material 210 that can be subsequently removed from the substrate 300. For example, the mold layer 200 can include any mold material 210 that can be subsequently removed from the substrate 300 with an etching process, such as a wet etching process, a dry etching process, a reactive ion etching process, a plasma etching process, an isotropic etching process, an anisotropic etching process, an acidic etching process, a chemically-selective etching process, etc. For example, the mold material 210 of the mold layer 200 can include aluminum (Al), Si, silicon carbide (SiC), Si3N4, SiO2, copper (Cu), or a combination thereof. In various examples, the mold material 210 of the mold layer 200 includes any electron beam lithography resist material and/or a photolithography resist material. The mold material 210 of the mold layer 200 can be applied and/or deposited on the substrate 300.

The mold layer 200 can have a mold thickness M. The mold layer 200 can have a mold thickness M that extends across at least a portion of the surface of the substrate 300. In various examples, the mold layer 200 can have a mold thickness M that is less than 5 microns, such as less than 2 microns, such as less than 1 micron, such as less than 500 nanometers. As will become apparent with the present disclosure, the mold thickness M can substantially correspond (e.g., within a five percent difference) to a height H (FIG. 1D) of at least one feature 400 of the component 100. The height H of the at least one feature 400 of the component 100 may be less than 5 microns, such as less than 2 microns, such as less than 1 micron, such as less than 500 nanometers.

In various examples, the at least one feature 400 can be formed on the substrate 300 by forming at least one cavity 250 in the mold layer 200 that is on the substrate 300, as depicted in FIG. 1B. Forming the at least one cavity 250 can include forming the at least one cavity 250 completely through a mold thickness of the mold layer 200. For example, the at least one cavity 250 may extend completely through the mold layer 200 and to the substrate 300.

In various examples, at least a portion of the mold material 210 of the mold layer 200 can be removed with a wet chemical etching process to form each cavity 250. The wet chemical etching process may be any etching process that uses liquid chemicals or etchants to remove the portion of the mold material 210 of the mold layer 200. In various example, at least a portion of the mold material 210 is removed with potassium hydroxide (KOH) in a wet chemical etching process to form each cavity 250. Each cavity 250 may have any shape. For example, and as depicted in FIG. 1B, the resulting cavity 250 can define an inverted frustrum shape. In various examples, the resulting cavity 250 can define an inverted pyramid shape. Other shapes for each cavity 250 are contemplated, such as a half-sphere shape or a shape that includes spherically-shaped regions.

Each cavity 250 can define an opening in the mold layer 200. The opening of each cavity 250 can define a distance D. As will become apparent in light of the present disclosure, the distance D defined by the opening of each cavity 250 in the mold layer 200 can substantially correspond to a width W (FIG. 1D) of an upper portion of the resulting feature 400 that is formed within the respective cavity 250. The distance D defined by the opening of each cavity 250 and the width W of an upper portion of the resulting at least one feature 400 may be less than 5 microns. In various examples, the width W and/or the distance D may be a “critical dimension”, a term of art in lithography, which may be measured at a specific height above the substrate 300.

In various examples, and with reference to FIG. 1C, each feature 400 can be formed on the substrate 300 by applying a feature material 410 within each cavity 250 and on the substrate 300. The feature material 410 may be any material. For example, the feature material 410 may be or comprise a conductive material, such as a metallic material, such as aluminum, copper, tungsten, or a combination thereof. The feature material 410 may be or comprise an insulative material, such as a dielectric material, such as an oxide (e.g., silicon dioxide), a nitride, silicon, or a combination thereof. In various examples, a plurality of different feature materials 410 are use. For example, a first feature material 410 can be applied within a first cavity 250 and a second feature material 410 can be applied within a second cavity 250. The first feature material 410 may be a conductive material whereas the second feature material 410 may be an insulative material. In various examples, both the first feature material 410 and the second feature material 410 are conductive materials, but the first feature material 410 may be different than the second feature material 410. Similarly, both the first feature material 410 and the second feature material 410 may be insulative materials, but the first feature material 410 may be different than the second feature material 410.

The feature material 410 can be applied within each cavity 250 with a conformal chemical vapor deposition process. For example, the feature material 410 can be applied within each cavity 250 with a chemical vapor deposition (CVD) process. The CVD process can be an atomic layer deposition (ALD) process. The ALD process is a deposition technique that may deposit highly conformal coatings on substrates with a controlled and uniform thickness. The ALD process can include adding a first precursor to a reaction chamber that contains the substrate 300 and the at least one cavity 250 to be filled. After the first precursor is absorbed by the substrate 300 and the mold material 210 of the mold layer 200, the first precursor can be removed from the reaction chamber and a second precursor can be added to the chamber to react with the first precursor, which may create a layer on the surface of the substrate 300 and/or on an inner wall of the cavity 250 to be filled. The second precursor can then be removed from the reaction chamber and the process can be repeated until the first material fills each cavity 250.

In various examples, the feature material 410 can be applied within each cavity 250 with a physical vapor deposition (PVD) process, such as sputtering and evaporation. The PVD process is a process where a solid material is vaporized in a vacuum and deposited onto a substrate 300 and/or within the cavity 250 of the mold layer 200. In various examples, the feature material 410 can be applied on the substrate 300 and/or within the cavity 250 of the mold layer 200 with a flux-controlled CVD process. In various examples, the feature material 410 can be applied on the substrate 300 and/or within the cavity 250 of the mold layer 200 with an electroplating process.

In various examples, an overburden removal step can be performed. For example, and as will be appreciated in light of the present disclosure, when the feature material 410 is applied within each cavity 20, the feature material 410 may also be deposited on a top surface 201 of the mold layer. Having the feature material 410 present on the top surface 201 may be unintentional or undesirable. As such, the portions of the feature material 410 that are positioned higher than the top surface 201 of the mold layer may be removed with an overburden removal step.

In various examples, and with reference to FIG. 1D, each feature 400 can be formed on the substrate 300 by removing the mold layer 200 from the component 100. The mold layer 200 can be removed from the component 100 with an etching process, such as a wet etching process, a dry etching process, a reactive ion etching process, a plasma etching process, an isotropic etching process, an anisotropic etching process, an acidic etching process, a chemically-selective etching process, etc. The feature material 410 that remains on the substrate 300 after the mold layer 200 is removed may define the at least one feature 400.

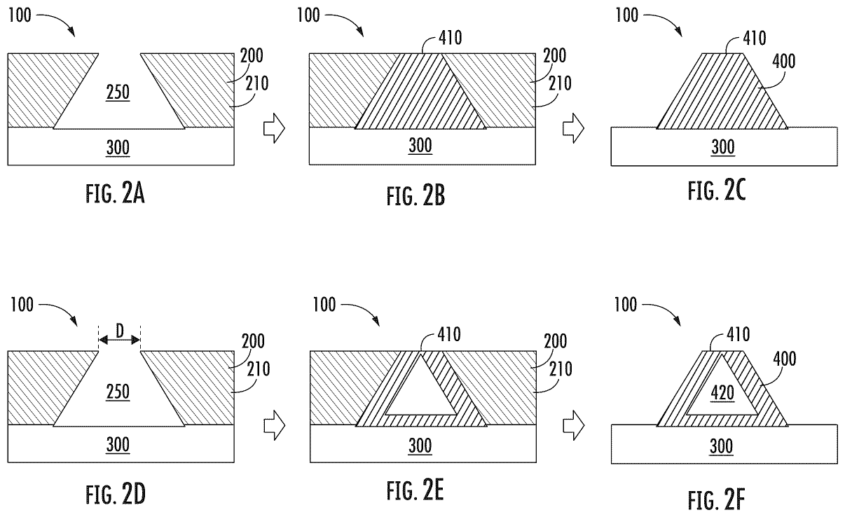

Referring now to FIGS. 2A-2F, cross-sectional, side views of at least a portion of a component 100 during various manufacturing stages are provided, in accordance with an example embodiment. The component 100 of FIGS. 2A-2F can be manufactured the same as, or similarly to, the component 100 of FIGS. 1A-1D. For example, at least a portion of the mold material 210 of the mold layer 200 can be removed with a wet chemical etching process to form each cavity 250. As depicted, the cavity 250 formed within the mold layer 200 can define a frustrum shape. In various examples, the cavity 250 formed within the mold layer 200 can define a pyramid shape.

With reference to FIG. 2E, when the feature material 410 is applied within each cavity 250 with a conformal deposition process, such as a conformal chemical vapor deposition process, the feature material 410 may conformally coat the inner walls of the cavity 250. When the cavity 250 has a reentrant shape (e.g., the cavity 250 has a larger cross-sectional area near the substrate 300 than near the opening of the cavity 250), such as a pyramid or frustrum shape, the coating may also close the cavity 250 once the thickness of the feature material 410 exceeds half of the distance D defined by the cavity 250. As such, a void 420 may be formed within the feature material 410 that defines the at least one feature 400. When the at least one feature 400 is formed on the substrate 300 in a low pressure environment (e.g., less than 1 millibar), such as an ultra-high vacuum environment (e.g., less than 1.0×10−8 millibar), a low pressure environment, such as an ultra-high vacuum environment, can exist within the void 420.

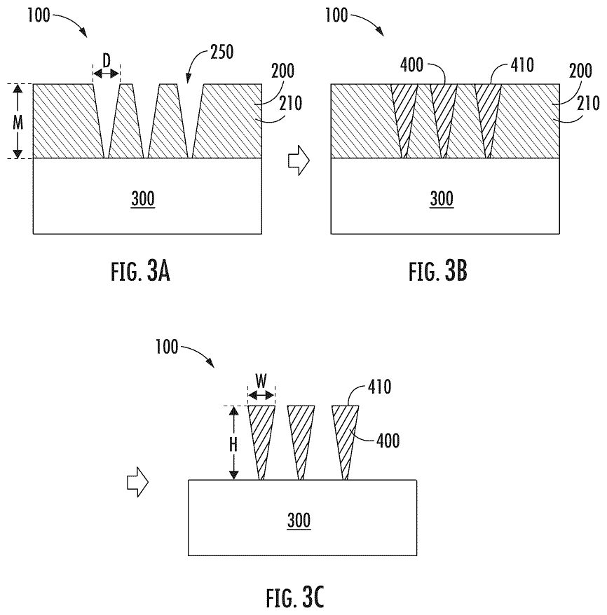

Referring now to FIGS. 3A-3C, cross-sectional, side views of at least a portion of a component 100 during various manufacturing stages are provided, in accordance with an example embodiment. The component 100 of FIGS. 3A-3C can be manufactured the same as, or similarly to, any of the components as described with reference to FIGS. 1A-2F. In various examples, and with reference to FIG. 3A, forming the at least one cavity 250 in the mold layer 200 includes removing a portion of the mold material 210 with a dry etching process, such as a reactive ion etching process, to form the at least one cavity 250. A dry etching process may remove the mold material 210 by exposing the mold material 210 to a continuous flow of particles, such as ions, electrons, or photons. The kinetic energy of the particles may knock out the atoms of the mold material 210. As will be appreciated, dry etching processes often result in reduced etching as the portion of the mold material 210 is removed, which may result in a tapered shape, such as an inverted conical shape, as depicted in FIG. 3A. The tapered shape of the cavity 250 may result in a feature 400 that also has a tapered shape, as depicted in FIG. 3C.

The dry etching process may be used to form high-aspect cavities 250, which may result in the formation of high-aspect features 400. For example, the dry etching process may be used to form a cavity 250 that extends completely through a mold thickness M of the mold layer 200 and defines an opening that defines a distance D. The mold thickness M may be greater than the distance D defined by the opening of the cavity 250. The resulting feature 400 may have a height H that is greater than a width W.

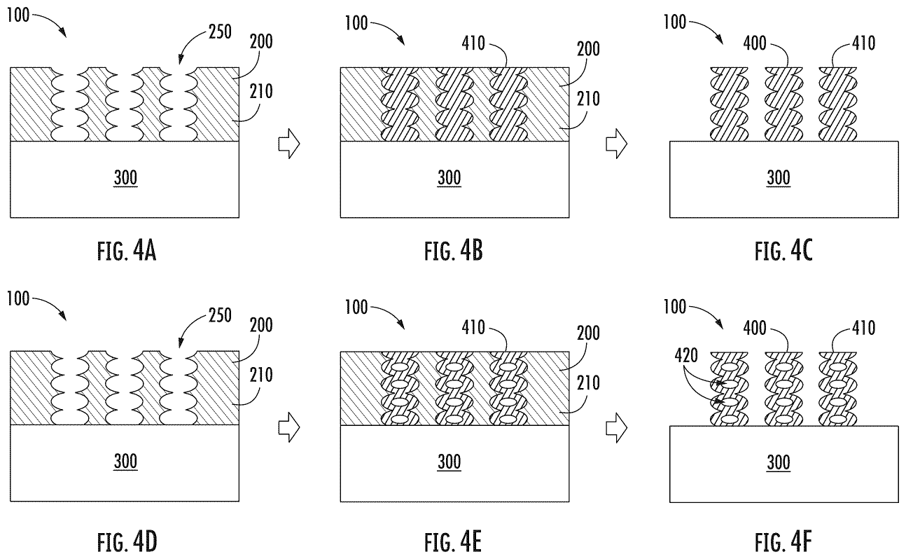

Referring now to FIGS. 4A-4F, cross-sectional, side views of at least a portion of two components 100 during various manufacturing stages are provided, in accordance with an example embodiment. The components 100 of FIGS. 4A-4F can be manufactured the same as, or similarly to, any of the components as described with reference to FIGS. 1A-3C. In various examples, forming the at least one cavity 250 in the mold layer 200 may include removing a portion of the mold material 210 with alternating steps of etching the mold material 210 and passivating the mold material 210. In various examples, etching the mold material 210 may include etching the mold material 210 with sulfur hexafluoride (SF6). Passivating the mold material 210 may include passivating the mold material 210 with octafluorocyclobutane (C4F8).

The two-step process of alternating steps of etching and passivating the mold material 210 may result in a cavity 250 that defines a scallop shape, as depicted in FIGS. 4A and 4D. For example, the inner walls of each cavity 250 may define a plurality of parabolic-shaped inner walls that collectively extend vertically. After each cavity 250 is filled with the feature material 410, as depicted in FIGS. 4B and 4E, and the mold material 210 subsequently removed, as depicted in FIGS. 4C and 4F, the resulting at least one feature 400 can have a scallop shape. In various examples, the outer surface of the at least one feature 400 may define a plurality of parabolic-shaped outer surfaces.

In various examples, and as depicted in FIG. 4E, a plurality of voids 420 may be formed within the feature material 410 that is applied within the cavity 250, which may result in a plurality of voids 420 being formed within the resulting feature 400, as depicted in FIG. 4F. A low-pressure environment, such as an ultra-high vacuum environment, may exist in each of the plurality of voids 420 when the component 100 is manufactured in a low-pressure environment, such as an ultra-high vacuum environment. As already discussed, each of the plurality of voids 420 being formed within the feature material 410 may be a result of the feature material 410 being applied with a conformal deposition process, such as a conformal chemical vapor deposition process.

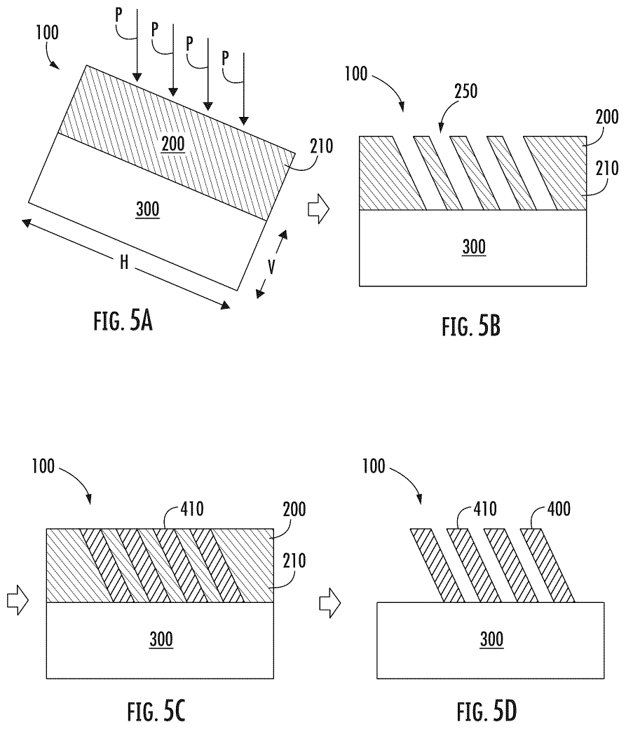

Referring now to FIGS. 5A-5D, cross-sectional, side views of at least a portion of a component 100 during various manufacturing stages are provided, in accordance with an example embodiment. The component 100 of FIGS. 5A-5D can be manufactured the same as, or similarly to, any of the components as described with reference to FIGS. 1A-4F. As previously discussed, forming the at least one cavity 250 in the mold layer 200 may include removing a portion of the mold material 210 with a dry etching process, such as a reactive ion etching process, which may expose the mold material 210 to a continuous flow of particles, such as ions, electrons, or photons, to form the at least one cavity 250. The particles may travel in a direction P towards the mold layer 200 to remove one or more portions of the mold material 210.

In various examples, forming the at least one cavity 250 may include positioning the substrate 300 and/or the mold layer 200 at an angle relative to a direction P of travel of particles being used in the dry etching process, such as a reactive ion etching process, as depicted in FIG. 5A. Positioning the substrate 300 and/or the mold layer 200 at an angle relative to a direction P of travel of the particles may form at least one feature 400 that has a slanted configuration such that each feature 400 has a varying cross-sectional position along at least two planes that are parallel to the horizontal plane defined by the surface of the substrate 300. The angle may be at least 5 degrees and up to 85 degrees, such as at least 45 degrees and up to 85 degrees, relative to the horizontal plane defined by the surface of the substrate 300.

In various examples, each feature 400 has a varying cross-sectional position along at least two planes that are parallel to the horizontal plane defined by the surface of the substrate 300, but can have a consistent cross-sectional shape along those two planes. Stated differently, each feature 400 can have a consisted shape, but may be slanted relative to the horizontal plane defined by the substrate 300. In various examples, each feature 400 may have an inconsistent shape. For example, and as discussed, the dry etching process may result in a tapered shape of each feature 400, as depicted in FIG. 3C. As such, each feature 400 may be tapered and slanted relative to the horizontal plane defined by the substrate 300. In yet another example, the two-step etch process as described with reference to FIGS. 4A-4F may be used, along with positioning the substrate 300 at an angle, to form features 400 that have a scallop shape and are also tilted.

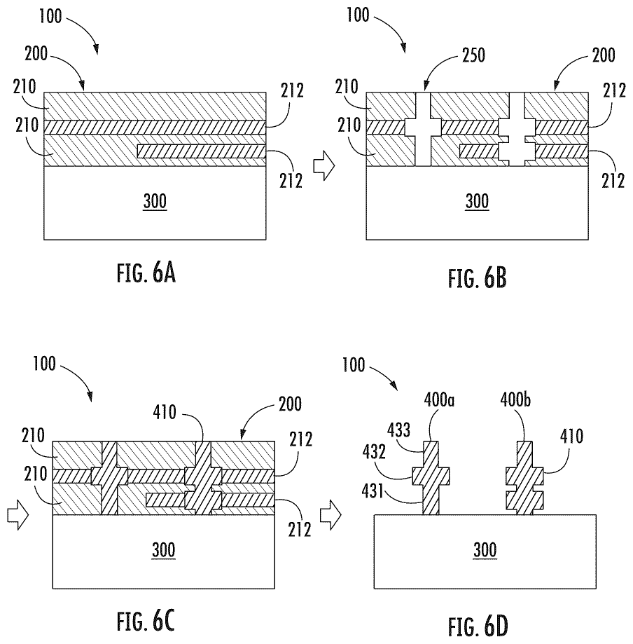

Referring now to FIGS. 6A-6D, cross-sectional, side views of at least a portion of a component 100 during various manufacturing stages are provided, in accordance with an example embodiment. The component 100 of FIGS. 6A-6D can be manufactured the same as, or similarly to, any of the components as described with reference to FIGS. 1A-5D. In various examples, the mold layer 200 may include a plurality of different mold layers 200. For example, at least one layer may include the mold material 210 and at least another layer may include a second mold material 212. In various examples, the mold material 210 is silicon and the second mold material 212 is silicon oxide, or vice-versa.

The mold layer 200 may be formed by depositing a layer of the mold material 210 on the substrate 300, depositing a masking layer (not depicted) on at least a portion of the layer that includes the mold material 210, depositing another layer with the second mold material 212 on the layer that includes the mold material 210, subsequently removing the masking layer, depositing another layer of the mold material 210, etc.

As used herein, the term “layer” should be understood to mean a singular layer or a plurality of layers of the same material. As will be appreciated by those skilled in the art, common deposition methods involve depositing a plurality of thin layers to form a “layer”. Therefore, even though the term “layer” is often used herein in the singular, it should be understood that a layer may include a plurality of layers of the same material. As such, “depositing a layer of the mold material 210” may refer to depositing a plurality of thin layers of the mold material 210, “depositing a masking layer” may refer to depositing a plurality of thin layers of a masking material, etc. In an example embodiment, a thin layer consists of one to a dozen atomic layers of a respective material.

In various examples, and as depicted in FIG. 6A, each mold layer 200 that includes the second mold material 212 may be distinct from the other layers that comprise the second mold material 212. In other words, each mold layer 200 that includes the second mold material 212 may be separated by a layer that includes the mold material 210 or another mold material 210, such as a third mold material 210, a fourth mold material 210, etc. As also depicted in FIG. 6A, at least one of the layers that includes the second mold material 212 may have a same thickness than another one of the layers that includes the second mold material 212. The layers that include the second mold material 212 and have the same thickness may also have different volumes, as depicted in FIG. 6A. Stated differently, the layers that include the second mold material 212 and have the same thickness may not extend horizontally the same distance. In various examples, at least one of the layers that includes the second mold material 212 may have a portion that is not vertically aligned with at least one other layer that comprises the second mold material 212.

In various examples, at least one of the layers that includes the second mold material 212 may have a different thickness than another one of the layers that includes the second mold material 212. In various examples, the at least one layer that includes the mold material 210 may have the same, or a different thickness than the at least one layer that includes the second mold material 212.

In various examples, forming the at least one cavity 250 in the mold layer 200 may include using a single etch process that may etch the mold material 210 differently than the second mold material 212, as depicted in FIG. 6B. For example, the single etch process may result in a vertical etch component and an isotropic etch component of each the mold material 210 and the second mold material 212. The rate of the vertical etch component and/or the isotropic etch component may be higher for the mold material 210 than the second mold material 212, or vice-versa. In various examples, forming the at least one cavity 250 in the mold layer 200 may include using a single etch process that will etch the mold material 210 vertically and the second mold material 212 isotropically. As another example, the single etch process may etch both the mold material 210 and the second mold material 212 isotropically. For example, forming the at least one cavity 250 may include using a reactive ion etching process that has a chemical etch rate that etches the second mold material 212 at a faster rate than the mold material 210. As will be appreciated in light of the present disclosure, the reactive ion etching process may etch both the mold material 210 and the second mold material 212 vertically, but only the second mold material 212 may be etched laterally at a meaningful rate. For example, the second mold material 212 may be etched at a rate that is at least two times faster, such as at least five times faster, such as at least ten times faster than the mold material 210.

After the cavity 250 is filled, as depicted in FIG. 6C, and the mold layer 200 removed, as depicted in FIG. 6D, each resulting feature 400 may have a first portion 431 that has a first horizontal thickness, a second portion 432 that has a second horizontal thickness, and a third portion 433 that has a third horizontal thickness. A first percent difference between the first horizontal thickness and the second horizontal thickness may be at least 5 percent and up to 200 percent, such as at least 5 percent and up to 100 percent, such as at least 5 percent and up to 100 percent. A second percent difference between the first horizontal thickness and the third horizontal thickness may be less than 5 percent, such as less than 1 percent. Stated differently, the feature 400 may have varying thickness at different portions of the feature 400.

In various examples, and as depicted in FIG. 6D, one of the features 400a may have a different shape than at least another feature 400b. For example, at least one of the first feature 400a or the second feature 400b may include at least one protrusion that extends horizontally. The second feature 400b may include more protrusions than the first feature 400a. Forming features 400 of different shapes may be a result of applying the masking layer so that at least one layer that includes the second mold material 212 has a portion that is not vertically aligned with at least one other layer that comprises the second mold material 212.

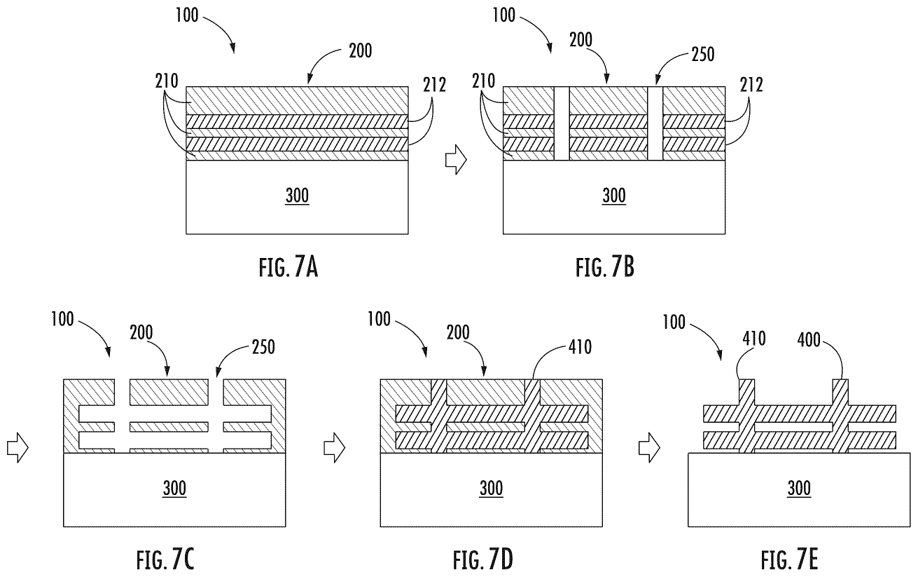

Referring now to FIGS. 7A-7E, cross-sectional, side views of at least a portion of a component 100 during various manufacturing stages are provided, in accordance with an example embodiment. The component 100 of FIGS. 7A-7E can be manufactured the same as, or similarly to, any of the components as described with reference to FIGS. 1A-6D. For example, the component 100 of FIGS. 7A-7E can be manufactured the same as, or similarly to, the component of FIG. 6A-6D. As discussed, and as depicted in FIG. 7A, the mold layer 200 can include a plurality of mold layers 200, which may include at least one layer of the mold material 210 and at least another layer of the second mold material 212.

In various examples, each cavity 250 can be formed by etching the mold material 210 and the second mold material 212 vertically, as depicted in FIG. 7B, and etching the second mold material 212 with a second etching process that is chemically selective to etch the second mold material 212 isotropically, as depicted in FIG. 7C. After each cavity 250 is filled with the feature material 410, as depicted in FIG. 7D, and the mold material 210 removed, as depicted in FIG. 7E, each resulting feature 400 may have a three-dimensional lattice shape.

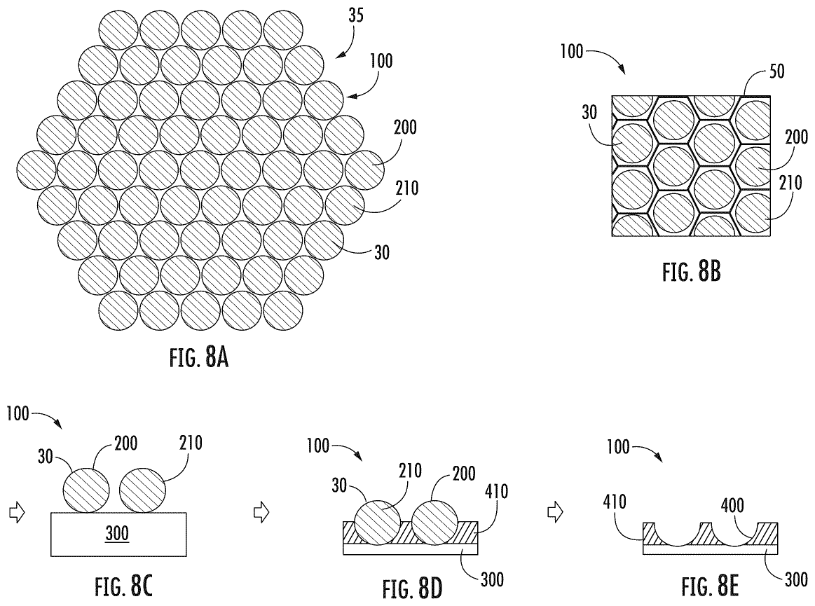

Referring now to FIGS. 8B-8E, various views of at least a portion of a component 100 during various manufacturing stages are provided, in accordance with an example embodiment. FIG. 8B provides a top view and FIGS. 8C-8E provide cross-sectional, side views of at least a portion of a component 100 during various manufacturing stages, in accordance with an example embodiment. The component 100 of FIGS. 8B-8E can be manufactured the same as, or similarly to, any of the components as described with reference to FIGS. 1A-7E.

In various examples, forming the at least one feature 400 on a substrate 300 may include bonding at least one self-assembled structure 30 on the substrate 300, as depicted in FIG. 8C. Each self-assembled structure 30 may be a self-assembled nanosphere, such as a self-assembled polystyrene nanosphere or a silica (SiO2) nanosphere.

In various examples, each self-assembled structure 30 can be arranged on the substrate in a self-organized arrangement 35. For example, and as depicted in FIG. 8A, a plurality of self-assembled structures 30 can be suspended in a liquid suspension. The self-assembled structures 30 can be suspended in the liquid suspension on top of the substrate 300. In various examples, each self-assembled structure 30 may be colloidal such that the self-assembled structures 30 are substantially evenly distributed in the liquid suspension. The liquid suspension can be subsequently evaporated. As will be appreciated, as the liquid suspension is evaporated, the plurality of self-assembled structures 30 are attracted to each other and consolidate into a self-organized arrangement 35. A confinement device (not depicted), such as a microscope cover glass, may be used to prevent the self-organized arrangement 35 of self-assembled structures 30 from assembling vertically such that some self-assembled structures 30 are positioned on top of other self-assembled structures 30 instead of on the substrate 300. In various examples, a confinement device is not used and the self-assembled structures 30 are allowed to form a self-organized arrangement 35 that has multiple layers of self-assembled structures 30. In various examples, and as depicted in FIG. 8A, the self-organized arrangement 35 may be hexagonal shaped.

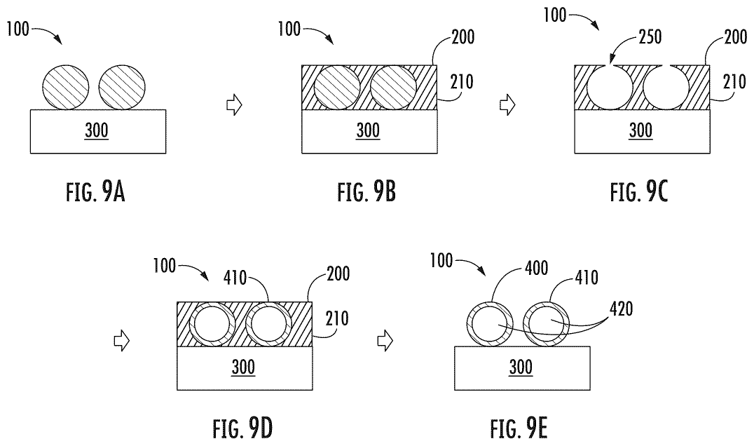

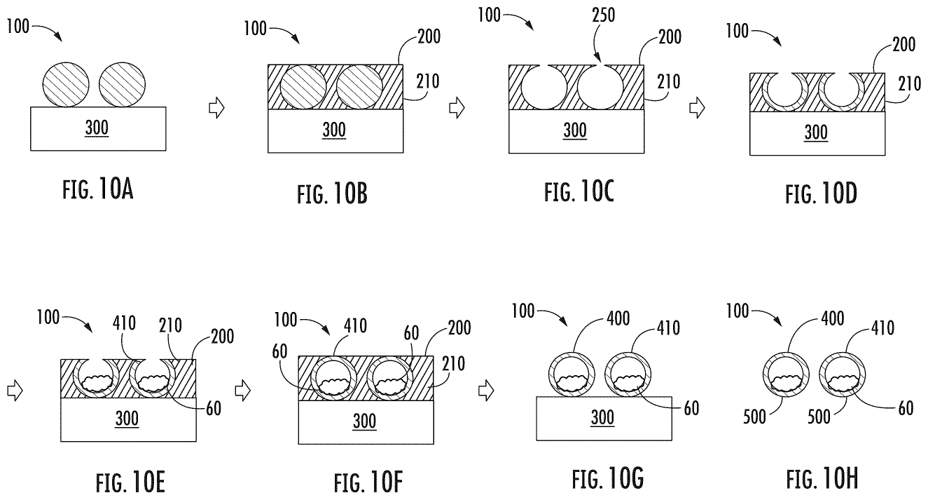

The self-organized arrangement 35 may compact as the liquid suspension is evaporated further, which may deform each self-assembled structure 30 to be hexagonal. In various examples, and as depicted in FIG. 8A, each self-assembled structure 30 may comprise of a material (e.g., a mold material 210, as discussed with reference to FIGS. 8C-8E, or a feature material 410, as will be discussed with reference to FIGS. 9A-10H.

In various examples, and as depicted in FIG. 8B, a lattice tool 50 may be positioned on the substrate 300. The lattice tool 50 may define a plurality of spaces and a plurality of self-assembled structures 30 may be positioned within the lattice tool 50. For example, each self-assembled structure 30 may be positioned within a respective space of the plurality of spaces defined by the lattice tool 50 and subsequently bonded to the substrate 300.

In various examples, a feature material 410 may be applied on the substrate 300 and around each self-assembled structure 30, as depicted in FIG. 8D. As such, each self-assembled structure 30 may serve the purpose of a mold layer 200. The feature material 410 may be applied such that the feature material 410 does not completely cover the self-assembled structure 30. For example, the feature material 410 may be applied such that about half, such as at least 30 percent and up to 70 percent, such as at least 30 percent and up to 50 percent, of a diameter of each self-assembled structure 30 is covered with the feature material 410. In various examples, self-assembled structures 30 of various sizes may be bonded to the substrate 300. As such, the amount that each self-assembled structure 30 is covered with the feature material 410 may also vary.

In various examples, the self-assembled structure 30 may be removed from the substrate 300 and from the feature material 410 to form the feature 400, as depicted in FIG. 8E. The self-assembled structure 30 may be removed from the substrate 300 mechanically, chemically, or thermally. Once each self-assembled structure 30 is removed from the substrate 300 and from the feature material 410, the resulting feature 400 may have a portion that has a concave shape or each feature 400 may have a plurality of portions that each have a concave shape.

The feature material 410 may be a reflective material having a reflectivity of at least 90%. In various examples, the feature material 410 may not have a reflectivity of at least 90%, but a reflective coating can be applied on each feature 400 that has a reflectivity of at least 90%. Applying reflective coating or using a reflective material as the feature material 410 has various benefits. For example, the resulting feature 400 may be used as a high-reflectivity focusing mirror.

Referring now to FIGS. 9A-9E, cross-sectional, side views of at least a portion of a component 100 during various manufacturing stages are provided, in accordance with an example embodiment. The component 100 of FIGS. 9A-9E can be manufactured the same as, or similarly to, any of the components as described with reference to FIGS. 1A-8E. In various examples, the self-assembled structure 30 may be applied to the substrate 300, as previously described with reference to FIGS. 8A-8E. A mold layer 200 may be applied on the substrate 300 and around the self-assembled structure 30, as depicted in FIG. 9B. The mold layer 200 may be applied on the substrate 300 and around the self-assembled structure 30 such that a majority of the self-assembled structure 30 is covered. For example, the mold layer 200 may be applied such that at least 50% and up to 98%, such as at least 75% and up to 98%, such as at least 85% and up to 98% of a diameter of the self-assembled structure 30 is covered with the mold layer 200. Each self-assembled structure 30 may be removed from the mold layer 200 mechanically, chemically, or thermally, as depicted in FIG. 9C.

In various examples, the feature 400 can be formed by applying the feature material 410 within a cavity 250 that is formed in the mold layer 200 after removing each self-assembled structure 30 from the substrate 300 and from the mold layer 200. In various examples, a conformal deposition process can be used that may result in the opening of the cavity 250 being closed by the feature material 410. The resulting feature 400 may be spherical and may include a void 420 that is positioned within the resulting feature 400, as depicted in FIG. 9E.

Referring now to FIGS. 10A-10H, cross-sectional, side views of at least a portion of a component 100 during various manufacturing stages are provided, in accordance with an example embodiment. The component 100 of FIGS. 10A-10H can be manufactured the same as, or similarly to, the component 100 as described with reference to FIGS. 9A-9E. For example, at least one self-assembled structure 30 may be bonded to the substrate 300, the mold layer 200 may be applied around the self-assembled structure 30, and the self-assembled structure 30 may be subsequently removed, as depicted in FIGS. 10A-10C.

In an example embodiment, the self-assembled structures 30 are nanometer-scale spheres made of Styrofoam and/or another material. While the self-assembled structures 30 are shown as spheres, in various embodiments, the self-assembled structures 30 may have a variety of shapes. For example, the self-assembled structures 30 may be extruded structures and/or the like.

In various examples, the feature material 410 may be applied within the cavity 250, but the feature material 410 may not completely close the opening or completely form a spherical shape. Instead, an opening may remain in the feature material 410, as depicted in FIG. 10D. In various examples, a substance 60 may be positioned within the open spherical shape, as depicted in FIG. 10E. The substance 60 may be a medicinal substance 60.

The open spherical shape defined by the feature material 410 may be subsequently enclosed after positioning the substance 60 within the open spherical shape, as depicted in FIG. 10F. For example, additional feature material 410 may be applied to the open spherical shape, which may encapsulate the substance 60 within the resulting shape, as depicted in FIG. 10G.

In various embodiments, and as depicted in FIG. 10H, the feature material 410 is removed from the substrate 300 for use. For example, the feature material 410, when removed from the substrate 300, may form one or more nanometer-scale structures 500, such as nanoparticles. For example, the nanoparticles may be used to deliver the substance 60 to a target. For example, the nanoparticles may be injected or otherwise delivered into the interior of a living being (e.g., animal, plant, and/or the like) and then caused to burst and/or break open by applying electromagnetic radiation of a wavelength/frequency selected based on the material used as the feature material 410. For example, the electromagnetic radiation may be directed and/or focused on the target to only cause the nanoparticles disposed at or near the target to burst or break open. The substance 60 may then be delivered to the interior of the living being from the burst and/or broken open nanoparticles to provide a therapeutic effect and/or to aid in various types of imaging (e.g., as a contrast agent and/or marker). In an example embodiment, the nanometer-scale structures are quantum dots.

The feature material 410 may be removed from the substrate 300, which may form one or more nanometer-scale structures 500, mechanically or chemically. For example, the bond between the feature material 410 and the substrate 300 may be broken using a mechanical agitation method, such as sonication or applying a pressurized fluid, such as a gas (e.g., air or nitrogen) or liquid (e.g., water) onto the feature material 410 to mechanically force the feature material 410 from the substrate 300. In various examples, the feature material 410 may be removed from the substrate 300 by applying a sacrificial layer (not depicted) on the substrate 300 prior to applying the feature material 410 onto the substrate 300. The sacrificial layer may be removed by a removal process, such as a selective etching process or a dissolving process using chemicals to release the feature material 410 from the substrate 300. The sacrificial layer may be water soluble or removable using a solvent, such as acetone.

The components as described in reference to FIGS. 1A-10G have various benefits. For example, and as will be appreciated by those skilled in the art in light of the present disclosure, conventional lithographically patterned features are often uniform in out-of-plane dimensions—the resulting shapes of the features are similar to an extrusion that only have a two-dimensional profile. Stated differently, conventional lithographically patterned features have a consistent cross-sectional shape, consistent cross-sectional size, and consistent cross-sectional position along a length of the conventional feature. In contrast, the resulting features 400 of the present disclosure may have a varying cross-sectional shape and/or size, as depicted in FIGS. 1D, 2F, 3C, 4C, 4F, 6D, 7E, 8E, 9E, and 10G. In various examples, and as depicted in FIG. 5D, the resulting features 400 of the present disclosure may have a consistent cross-sectional shape, but the cross-sectional position may vary relative to a vertical plane (i.e., the resulting feature 400 may be slanted relative to the vertical plane).

The resulting features 400 of the present disclosure that have a varying cross-sectional shape and/or varying cross sectional position may result in the fabrication of features 400 of particular shapes that may not be possible to achieve with conventional methods. For example, various quantum computing and photonic sensing components may be manufactured using the methods described herein that may not be manufacturable with conventional methodologies. In various examples, the disclosed methods of forming features 400 on a substrate 300 may be used to create features 400 for resonators, such as photonic resonators or phononic resonators. For example, the features 400 as described in reference to FIGS. 1A-4F may be used to manufacture resonators, such as photonic resonators or phononic resonators. In various examples, the disclosed methods of forming features 400 on a substrate 300 may be used to create features 400 for integrated lasers, three-dimensional metamaterials and photonic crystals. For example, the features 400 as described in reference to FIGS. 6D and 7E may be used to manufacture integrated lasers, three-dimensional metamaterials and photonic crystals. In various examples, the disclosed methods of forming features 400 on a substrate 300 may be used to create features 400 for nanoscale or microscale spherical mirrors. For example, the features 400 as described in reference to FIG. 8E may be used to manufacture nanoscale or microscale spherical mirrors.

### Conclusion

The above descriptions of various embodiments of the subject disclosure and corresponding figures and what is described in the Abstract, are described herein for illustrative purposes, and are not intended to be exhaustive or to limit the disclosed embodiments to the precise forms disclosed. It is to be understood that one of ordinary skill in the art may recognize that other embodiments having modifications, permutations, combinations, and additions can be implemented for performing the same, similar, alternative, or substitute functions of the disclosed subject matter, and are therefore considered within the scope of this disclosure. Therefore, the disclosed subject matter should not be limited to any single embodiment described herein, but rather should be construed in breadth and scope in accordance with the appended claims below. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1-42. (canceled)

43. A method of forming at least one feature on a substrate, the method comprising:
bonding a self-assembled structure on the substrate;
applying a feature material or a mold layer comprising a mold material on the substrate and around the self-assembled structure; and
removing the self-assembled structure from the substrate and from the feature material or the mold layer.

44. The method of claim 43, further comprising:
positioning a lattice tool on the substrate, wherein the lattice tool defines a plurality of spaces;
positioning a plurality of self-assembled structures within the lattice tool, wherein each self-assembled structure is positioned within a respective space of the plurality of spaces defined by the lattice tool; and
bonding each of the self-assembled structures on the substrate.

45. The method of claim 44, wherein the lattice tool is a hexagonal lattice tool.

46. The method of claim 43, wherein the self-assembled structure is a self-assembled nanosphere.

47. (canceled)

48. (canceled)

49. The method of claim 43, wherein the method further comprises:
arranging a plurality of self-assembled structures on the substrate in a self-organized arrangement by suspending the plurality of self-assembled structures in a liquid suspension; and
allowing the liquid suspension to evaporate.

50. The method of claim 49, wherein the plurality of self-assembled structures are suspended in the liquid suspension on top of the substrate.

51. The method of claim 43, wherein the method comprises applying the feature material on the substrate and around the self-assembled structure.

52. The method of claim 51, wherein the feature material is a dielectric material or a metallic material.

53. The method of claim 51, wherein the feature material is a reflective material having a reflectivity of at least 90%.

54. The method of claim 51, further comprising applying a reflective coating on the feature material, the reflective coating having a reflectivity of at least 90%.

55. (canceled)

56. The method of claim 43, wherein the method comprises applying the mold layer on the substrate and around the self-assembled structure, and wherein the method further comprises pplying the feature material within a cavity that is formed in the mold layer, wherein the cavity is formed after the removing the self-assembled structure from the substrate and from the mold layer, and wherein the feature material defines the at least one feature.

57. The method of claim 56, wherein the applying the feature material within the cavity comprises applying the feature material within the cavity with a conformal deposition process.

58. The method of claim 56, wherein the applying the feature material within the cavity comprises enclosing the cavity to form a void within the feature material that defines the at least one feature.

59. The method of claim 58, wherein the void comprises a low-pressure environment.

60. (canceled)

61. (canceled)

62. The method of claim 56, further comprising positioning or depositing a substance within the at least one feature, wherein the substance is a medicinal substance.

63. (canceled)

64. The method of claim 56, further comprising forming the cavity in the mold layer that is on the substrate, wherein forming the cavity comprises:
bonding a self-assembled structure on the substrate;
applying the mold layer on the substrate and around the self-assembled structure; and
removing the self-assembled structure from the substrate.

65. (canceled)

66. The method of claim 43, wherein the at least one feature formed on the substrate is for at least one of a component of an electrical or optical device or a nanoparticle.

67. A component for an electrical or optical device, the component comprising:
a substrate extending along a horizontal plane; and
at least one feature on the substrate, wherein:
the at least one feature comprises a feature material, and
the at least one feature has a varying cross-sectional shape or position along at least two other horizontal planes.

68-90. (canceled)

91. (canceled)

92. (canceled)

93. (canceled)

94. The component of claim 67, wherein the at least one feature has a plurality of portions that have a concave shape.

95. (canceled)

96. The component of claim 67, wherein the at least one feature has a spherical shape, wherein the at least one feature defines a void that is positioned within the at least one feature, wherein the at least one feature comprises a substance encapsulated within the at least one feature, and wherein the substance is a medicinal substance.

97. (canceled)

98. (canceled)

99. (canceled)

100. (canceled)

101. (canceled)
